(19) United States
(12) Patent Application Publication
(10) Pub. No.: US 2011/0174878 A1
(43) Pub. Date: Jul. 21, 2011

(54) PLANAR SENSOR STRUCTURE

(75) Inventors: Antti Ropponen, Helsinki (FI); Kai Kronström, Helsinki (FI); Otso Auterinen, Helsinki (FI)

(73) Assignee: MARIMILS OY, Vantaa (FI)

(21) Appl. No.: 12/988,749

(22) PCT Filed: Apr. 14, 2009
(86) PCT No.: PCT/FI2009/050275

§ 371 Date: Mar. 23, 2011

(30) Foreign Application Priority Data
Apr. 21, 2008 (FI) 20080301

(51) Int. Cl. G06K 7/10; G06K 7/01; G01R 31/04

(52) U.S. Cl. 235/439

(57) ABSTRACT

The sensor structure according to the invention comprises sensor elements for the detection of objects occurring by measuring an electrical connection and also one or more antenna loops for activating an escort memory tag in connection with reading it. With the loop antennas in the structure of the sensor field according to the invention the reading of an escort memory tag can be activated e.g. in a situation in which an object is detected using a sensor field, in which object an escort memory tag that can be activated with an excitation sent with a loop antenna can be disposed. An advantage of the structure according to the invention is the simplicity of the technical arrangement achieved, and lower costs and better physical durability than prior-art solutions.

### FIELD OF THE INVENTION

The object of this invention is a planar sensor structure, in connection with which is an antenna used in reading an escort memory tag.

### PRIOR ART

The use of a dense near-field sensor field in detecting presence is presented in U.S. Pat. No. 6,407,556B1, among others.

The use of pressure sensors to detect presence or movement is presented in U.S. Pat. No. 4,888,581A1, among others.

The use of a near-field sensor that is installed in the floor and measures an electrical connection for making observations is presented in application W02005020171A1, among others.

The excitation used in reading an escort memory tag in prior-art solutions is sent with antenna solutions, in which the antenna is a separate unit manufactured and installed for this purpose. The placement of the antenna so that the desired coverage area of the excitation sent is implemented and so that the escort memory tags disposed in exactly the desired area react to the excitation is problematic. The placement of the antenna so that the antenna does not get broken from physical stress exerted on it and so that the antenna does not form a visual detriment or obstruction is also often problematic.

### BRIEF DESCRIPTION OF THE INVENTION

The invention presents a planar sensor structure, in which an antenna that is used in reading an escort memory tag, i.e. an RFID identifier, is disposed.

The planar sensor structure according to the invention used in measuring an electrical connection, which sensor structure comprises at least one planar sensor element that conducts electricity and a first conductor connected to it, is characterized in that a second conductor is connected to the aforementioned sensor element or to the conductor connected to it such that the aforementioned conductors form, or the aforementioned conductors together with the sensor element form, a loop that is suited for sending an excitation used in reading an escort memory tag.

The sensor structure according to the invention can be intended e.g. for measuring an electrical connection in order to detect the presence or movement of objects in the proximity of the sensor.

The sensor structure according to the invention can be arranged such that the structure comprises a number of sensor elements and aforementioned first conductors, and a number of second conductors, and also such that the aforementioned conductors do not cross and are not positioned on the plane of the structure at the same point with each other but instead at the distance from each other required by electrical isolation. The structure can comprise one or more sensor elements, which are applicable for use as a ground plane in measuring an electrical connection. The sensor element used as a ground plane can be e.g. such that it is suited as a ground plane when using any sensor element whatsoever in the structure for measuring an electrical connection.

The sensor structure according to the invention can consist of a conductive material, which is disposed between insulating films such that the conductive material forms a sensor element. The conductive material can be e.g. an aluminum film, the thickness of which is 0.1 mm. In addition, the structure can be arranged so that the same conductive material also forms the aforementioned first and/or second conductor. The width of the conductors formed from the film can be e.g. 0.5 mm or 2 mm, and the conductor can be of different width in different points of the structure.

The structure according to the invention can be manufactured e.g. producing a pattern from one conductive layer by printing or etching, which pattern forms at least one sensor element and the aforementioned conductors.

The planar sensor structure according to the invention can be arranged so that the sensor elements are disposed in the structure one above the other and/or side by side such that the structure divides in its longitudinal direction into stages, in each of which at least one sensor element is disposed. The structure can be arranged such that the first conductor of each sensor element and a possible second conductor connected to the sensor element or to the first conductor is disposed in the structure such that no part of them is situated in the longitudinal direction of the structure on the first side of the stage containing the aforementioned sensor element.

Further, the structure can be arranged so that a borderline running from the first edge of the structure to its second edge separates two adjacent stages, which borderline does not dissect any sensor element and does not dissect any second conductor forming a loop or first conductor connected to a sensor element more than once.

Further, the structure can be arranged so that some of the aforementioned stages are such that the second conductor forming a loop crosses with the first borderline of the stage exactly once, which second conductor does not cross with the second borderline of the aforementioned stage. A stage arranged in this way contains a loop formed by the aforementioned second conductor.

The borderline between stages can be e.g. a straight line or a freely formed line according to the position of the sensor elements and the conductors.

Further, the sensor structure divided into stages by the aforementioned borderlines can be arranged so that one or more first or second conductors passing through a stage from its first borderline to its second pass at an angle with respect to the longitudinal direction of the structure such that the displacement corresponds to the amount of first conductors of the sensor elements and second conductors of the loops in the stage in question.

Yet again, the structure can be arranged so that adjacent stages are identical in terms of the shape and placement of a part or all of the conductors and sensor elements in it.

Further, a structure comprising consecutive stages that are identical in the aforesaid manner can be arranged so that the mat of the stage in the longitudinal direction, including the first and the second borderline, comprises a plurality of junctures disposed on the borderline such that both borderlines have a juncture at the same certain point of the borderline. When the junctures are numbered with the index i, which receive the values 1 . . . L, where L is the number of junctures, the juncture corresponding to the index i of the first borderline is connected with the conductor passing through the stage to the juncture of the second borderline, which juncture corresponds to the value i+K of the index, if this value is not greater than L, where K is the aggregate amount of sensor elements and loops disposed in the stage. The first conductors connected to the sensor elements disposed in a stage and the second conductors forming the loops disposed in the stage are connected to the junctures of the second borderline, which correspond to the values 1 . . . K of the index. Those junctures of the first borderline of the stage, for which the value i+K of the index i is greater than L, are not connected with a conductor of the structure to the juncture of the second borderline of the same stage. The values of the index i of the junctures presented do not need to correspond to the sequence of the junctures on the borderline, but a certain value of the index corresponds to the same location of the juncture on both the borderlines of the stage.

The structure according to the invention can be arranged so that from one to nine sensor elements, or many sensor elements, remain inside the loop formed by the second conductor. For example, in a linear structure, which comprises three sensor elements side-by-side, the second conductor can form a loop that extends in the longitudinal direction such that altogether nine sensor elements remain inside it.

The structure can be arranged so that the first and second conductors of two or more adjacent stages are disposed on the same side of the stage in the longitudinal direction of the structure.

The structure can be arranged so that the conductors connected to the sensor elements or loops of each stage extend in the structure to a certain distance from the stage in the longitudinal direction of the structure. The structure can be e.g. such that the first and second conductors pass through e.g. six or ten stages in the structure.

The structure can be arranged so that the first conductor of a sensor element extends in the structure to a certain distance in the longitudinal direction of the structure and the second conductor connected to the same sensor element or to the first conductor of it extends in the same direction to a certain different distance than the aforementioned first conductor. The structure can be e.g. such that the first and second conductors extend in the structure e.g. to a distance of three stages from the stage in which the sensor element is disposed, and the second conductors correspondingly to a distance of two elements.

The structure according to the invention can be arranged so that the first and second conductors pass on one or both edges of a structure comprising repetitive stages, in another point or in a number of points as viewed in the lateral direction of the structure. The structure can be e.g. such that the conductor connected to the sensor elements that are used as a ground plane passes on both edges of the structure and the other conductors in the center part of the structure.

In the structure according to the invention the sequence between the conductors at the point of the borderline of a stage can be such that the first conductors are in the same sequence with respect to each other as the sequence in which the corresponding sensors are disposed in the longitudinal direction of the structure. Further, the second conductors can be disposed next to the type of first conductor, which is connected to a sensor remaining inside a loop formed by the second conductor.

The structure can be arranged such that it can be manufactured to be continuous, so that the stage according to the pattern formed by the first conductor, the sensor element and the second conductor is repeated in it for the full longitudinal direction.

The structure according to the invention can e.g. be manufactured as a film-like mat, from which the necessary patches can be cut, which can be installed next to each other e.g. as a sensor field between the surface material of the floor and another structure of the floor. With the structure according to the invention measuring electronics can be connected to the manufactured sensor field e.g. by disposing a measuring apparatus at the end of the structure, which is formed by cutting the mat along the borderline of the stages or at some other point.

An advantage of the structure according to the invention with respect to prior art solutions is that the same structure can be advantageously used for sending an excitation used in reading an escort memory tag by connecting a suitable radio-frequency current to the loop and also e.g. as a sensor field that measures an electrical connection for detecting the presence and movement of objects, in which changes in a capacitive connection are measured e.g. between each sensor and the structure surrounding the sensor or between each sensor and other electrodes.

An advantage of the structure according to the invention can be that the excitation used in reading an escort memory tag is sent with the antenna solutions already implemented in connection with the sensor field without separate manufacturing or installation. Further, an advantage can be that the desired coverage area of the excitation sent can be implemented by using an antenna situated in exactly the right location, in which case the escort memory tags disposed in exactly the desired area react to the excitation. A further advantage can be that many antennas can be advantageously disposed in the structure and that they do not break easily from physical stress and they do not form a visual detriment or impediment.

An advantage of the structure according to the invention can be that the space taken by the conductors passing in the longitudinal direction of the structure is saved on the plane of the structure especially in its lateral direction. Two different conductors are not needed for one antenna formed by a loop. The distance required by e.g. the insulation between each conductor and the conductors takes space which, on the one hand, reduces the space in the width direction of the structure to be used for sensor electrodes and, on the other hand, limits the amount of conductors that fit in the structure, which in turn limits the amount of stages and sensor electrodes used and thus the maximum length of the viable mat to be installed. In the structure according to the invention, two antenna conductors are not needed in the longitudinal direction of the structure because the conductor of the sensor element is used as the second antenna conductor.

### DETAILED DESCRIPTION OF THE INVENTION

In the following the invention will be described in more detail with reference to the embodiments presented as examples and to the attached drawings, wherein

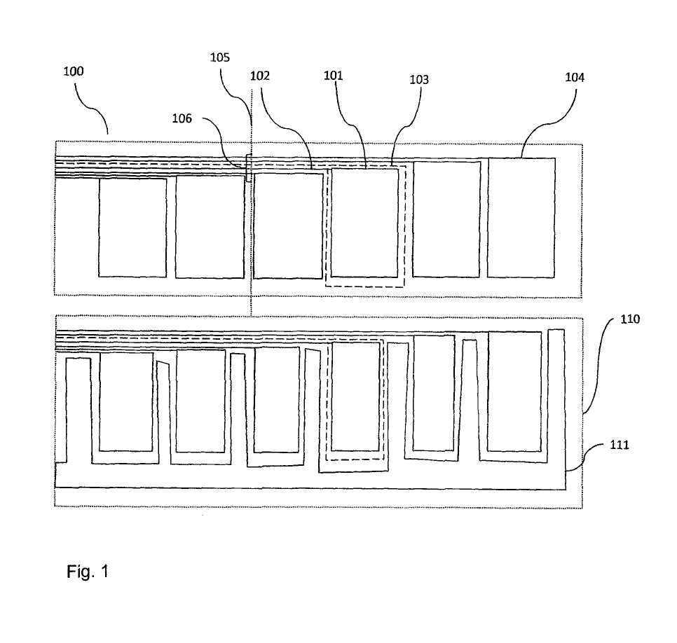

FIG. 1 presents two alternative sensor structures comprising one loop according to one embodiment of the invention.

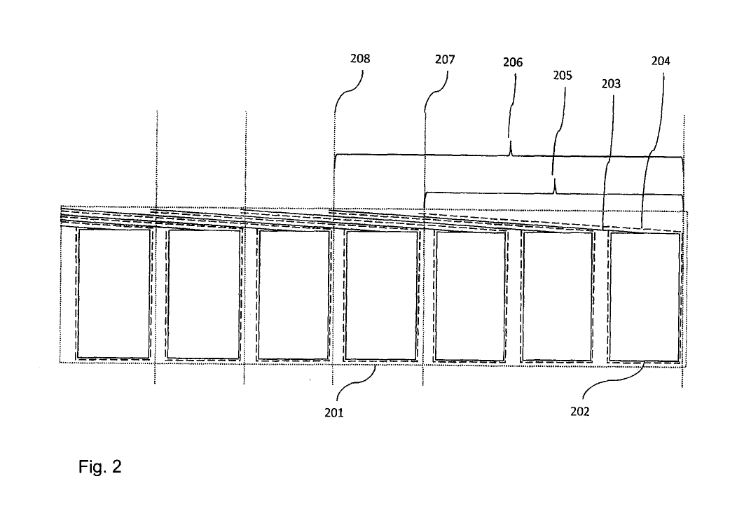

FIG. 2 presents a sensor structure comprising a number of loops according to a second embodiment of the invention.

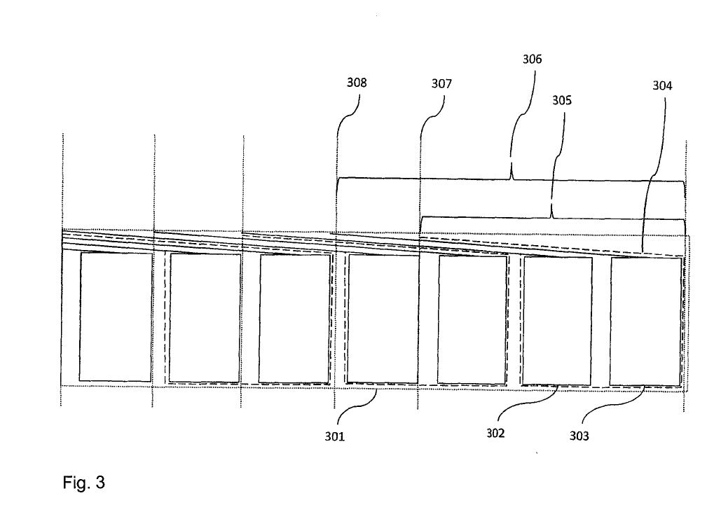

FIG. 3 presents a sensor structure comprising a number of loops according to a third embodiment of the invention.

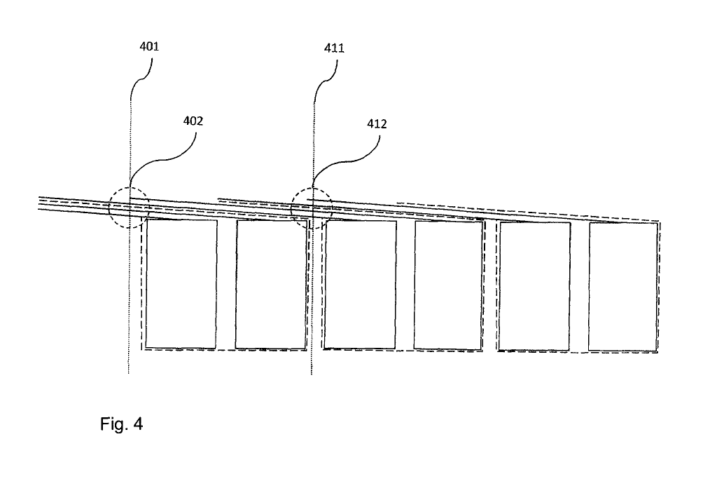

FIG. 4 presents a sensor structure comprising repetitive stages according to a third embodiment of the invention and the passage of the conductors on the borderline of the stages.

FIG. 1 presents a sensor structure (100), which comprises six conductive sensor elements, according to one embodiment of the invention. One of the sensor elements (101) and the first conductor (102) connected to it are arranged such that the conductor (102) forms together with a second conductor (103) a loop according to the invention, which is suited for sending a radio-frequency excitation used in the reading of an escort memory tag. The other sensor elements of the structure, e.g. that on the extreme right-hand side in the figure (104) or the first conductors connected to them are not connected to second conductors. All the conductors in the figure pass in the structure to the left-hand edge of it, on which can be installed a radio apparatus used for sending an excitation, an electronic apparatus or a connector used in measuring, to which the conductors connected to the radio apparatus or measuring apparatus are connected. The sensor structure (100) can be used when shorter by truncating it e.g. at any point whatsoever on the left-hand side of a sensor element (101) such that the loop remains intact and a new edge of the structure is created which can be used in the manner of the edge of the original structure for connecting conductors or an electronic apparatus. One possible truncation point (105), and the placement point (106) of the connector or apparatus corresponding to this, is marked in the figure. A connector similar to the connector in the case of an uncut structure (100), which penetrates the structure with pins at the point of each film-like conductor, can be used in this point. In the case of a connector comprising seven pins, here the two lowermost pins in the figure penetrate the structure at a point where there is no conductor. It is advantageous to use the structure (100) in solutions in which an excitation loop according to the invention is installed in the center section of the sensor field, from where the excitation to be sent reaches the desired space.

FIG. 1 also presents a structure (110), similar to the structure (100), according to a second embodiment of the invention, which comprises an element (111) used as a ground plane. This ground plane can be used for measuring an electrical connection with any second sensor element whatsoever of the same structure (110).

FIG. 2 presents the planar sensor structure (201) of a second embodiment of the invention, which comprises seven conductive sensor elements. A first conductor is connected to each sensor element, to which first conductor a second conductor is fitted such that a loop surrounding one sensor element is formed. In the figure the first conductor (203) of the sensor element (202) on the extreme right-hand side extends for a distance (206) of three sensor elements from the element (202). The second conductor (204) connected to the first conductor (203) of the same sensor element (202) extends for a distance of two sensor elements from the aforementioned element (202). The sensor structure (201) can be truncated at the point (207), in which case two sensor elements are formed. The part on the extreme right-hand side of the structure forms a structure that is disposed at the point (205) of the structure and comprises three sensor elements and three loops. At the point (207) on the left-hand edge of this structure is a point to which a connector, measuring apparatus and/or radio apparatus to be connected to the conductors of the structure can be installed. On the left-hand side of the truncation point (207) a sensor structure comprising four sensor elements and four loops is formed. The left-hand edge of this structure comprises a point to which a connector or measuring apparatus, which is connected to four first conductors and three second conductors, can be installed. This structure comprises three loops suited to sending an excitation used in reading an escort memory tag. The structure (201) comprises a second truncation point (208), by using which a structure of functionally the same type as the structure remaining on the left-hand side of the first truncation point (207) is formed. The structure (201) also comprises other advantageous truncation points, by using which the necessary sensor structure can be formed from the structure. The juncture of five conductors of the truncation point (207) is connected to the junctures of the truncation point (208) on the second borderline of the stage of the structure such that the two innermost junctures are used for the conductors of the sensor element and loop disposed in the stage. The two junctures of the truncation point (207) that are nearest the edge of the structure are not connected to the second borderline of the stage.

FIG. 3 presents the planar sensor structure (301) according to a third embodiment of the invention, which comprises seven conductive sensor elements, The sensor structure is similar to what is presented in FIG. 2. The second conductors of the structure pare arranged differently than in the structure presented in FIG. 2. The second conductor that is connected to the first conductor connected to the sensor element (302) forms a loop, inside of which remains the sensor element (303) in addition to the element (302). For example, the structure (305) or (306) can be formed from the structure (301) by truncating. By using the truncation point (307) a structure (305) is formed that comprises three sensor elements and one conductor loop, inside which remain two sensor elements (302,303). This loop is suited to sending an excitation according to the invention. By using the truncation point (308) a structure is formed from the left-hand part of the structure (301) that is functionally identically with the structure (305). By using the same truncation point (308) a structure (306) is formed from the part remaining on the right-hand side of it, which comprises four sensor elements, which remain as two pairs each of which is inside a separate conductor loop according to the invention. The second loop passes around the elements (302 and 303), but the second conductor of this loop does not extend to the truncation point (308), and thus cannot be connected to a connector or apparatus installed on the truncation point without a separate conductor.

FIG. 4 presents a sensor structure comprising repetitive stages according to a third embodiment of the invention. The figure presents a repetitive stage of the structure which is delimited between the borderlines (401) and (411). Both borderlines have a plurality of crossing points of conductors and a borderline, which form the junctures of consecutive stages. The junctures of the first borderline of the stage between the borderlines (401) and (411) are in the area (412) and the junctures of the second borderline are in the area (402). The junctures are numbered in the figure from bottom to top with the numbers 1 . . . 5. The junctures 1 and 2 of the first borderline are connected with a conductor running in the stage to the junctures 4 and 5 of the second borderline. The sensor elements disposed in the stage are connected with conductors to the junctures 1 and 2 of the second borderline, and the conductor forming a loop disposed in the stage to the juncture 3.

It is also obvious to the person skilled in the art that the exemplary embodiments presented above are for the sake of clarity comparatively simple in their structure and function. Following the model presented in this patent application it is possible to construct different and also very complex solutions that utilize the inventive concept presented in this patent application.

1. Planar sensor structure used in measuring an electrical connection, which comprises at least one planar sensor element that conducts electricity and a first conductor connected to it, characterized in that a second conductor is connected to the aforementioned sensor element or to the aforementioned conductor connected to it such that the first and the second conductor, or the aforementioned conductors together with the aforementioned sensor element, form a loop that is suited for sending an excitation used in reading an escort memory tag.

2. Planar sensor structure used in measuring an electrical connection, which sensor structure comprises at least two sensor elements, characterized in that the structure comprises first conductors and at least one second conductor connected to at least two sensor elements, which second conductor is connected to some sensor element or to the first conductor connected to it such that together the first conductor or the aforementioned sensor element and the first conductor connected to it form a loop, which is suited for sending an excitation used in reading an escort memory tag.

3. Sensor structure according to claim 2, characterized in that it is arranged such that the aforementioned at least two sensor elements are arranged one above the other and/or side by side such that the structure divides into at least two stages on at least one borderline passing through it, in each of which stages at least one sensor element is disposed, and also such that the first conductor connected to at least one sensor element disposed in each stage crosses with the first borderline of the aforementioned stage, and also such that the possible aforementioned second conductor connected to the sensor element disposed in the aforementioned stage or to the first conductor connected to it does not cross with any other borderline of the aforementioned stage than with the aforementioned first borderline.

4. Sensor structure according to claim 3, characterized in that the aforementioned conductors and sensor elements form a structure, in which the aforementioned at least two stages comprise the same pattern on the plane of the structure formed from the sensor elements, the first and the second conductors, which pattern is arranged such that there is a borderline between each two stages extending from one edge of the structure to the other, on which borderline is a plurality of junctures such that on the first and the second borderline of a stage is a juncture on the same certain point of the borderline such that when the junctures of the borderlines are numbered with the index i, which receives the values 1 . . . L, where L is the number of junctures, and the aggregate number of sensor elements disposed in a certain stage and loops disposed in a stage is K, the first conductors connected to the sensor elements disposed in a stage and the second conductors forming the loops disposed in the stage meet at the junctures of the second borderline, which have the index values 1 . . . K, and also such that the conductor meeting juncture i+K of the second borderline of the same stage passes through the stage without crossing with any conductor of the structure and meets the first borderline at the juncture i on it.

5. Sensor structure according to claim 4, characterized in that in the aforementioned stage the junctions disposed on its borderlines are connected such that the first conductor connected to a sensor element in a certain stage extends in the longitudinal direction of the structure through the adjacent stages longer than the second conductor connected to the sensor element disposed in the aforementioned stage or to the first conductor connected to it.

6. Sensor structure according to claim 1, characterized in that the structure comprises a conductive planar element, which is suited for use as a ground plane or as a similar type of means when using some sensor element, some sensor elements or all the said sensor elements for measuring an electrical connection.

7. Sensor structure according to claim 1, characterized in that the structure is arranged so that the aforementioned first and second conductors do not cross.

8. Sensor structure according to claim 1, characterized in that the structure is suited to measuring an electrical connection in order to detect the presence or movement of objects in the proximity of it.

9. Sensor structure according to claim 1, characterized in that at least one aforementioned second conductor forms a loop, inside which at most 9 sensor elements remain.

10. Sensor structure according to claim 2, characterized in that the structure comprises a conductive planar element, which is suited for use as a ground plane or as a similar type of means when using some sensor element, some sensor elements or all the said sensor elements for measuring an electrical connection.

11. Sensor structure according to claim 3, characterized in that the structure comprises a conductive planar element, which is suited for use as a ground plane or as a similar type of means when using some sensor element, some sensor elements or all the said sensor elements for measuring an electrical connection.

12. Sensor structure according to claim 4, characterized in that the structure comprises a conductive planar element, which is suited for use as a ground plane or as a similar type of means when using some sensor element, some sensor elements or all the said sensor elements for measuring an electrical connection.

13. Sensor structure according to claim 5, characterized in that the structure comprises a conductive planar element, which is suited for use as a ground plane or as a similar type of means when using some sensor element, some sensor elements or all the said sensor elements for measuring an electrical connection.

14. Sensor structure according to claim 2, characterized in that the structure is arranged so that the aforementioned first and second conductors do not cross.

15. Sensor structure according to claim 3, characterized in that the structure is arranged so that the aforementioned first and second conductors do not cross.

16. Sensor structure according to claim 4, characterized in that the structure is arranged so that the aforementioned first and second conductors do not cross.

17. Sensor structure according to claim 5, characterized in that the structure is arranged so that the aforementioned first and second conductors do not cross.

18. Sensor structure according to claim 6, characterized in that the structure is arranged so that the aforementioned first and second conductors do not cross.

19. Sensor structure according to claim 2, characterized in that the structure is suited to measuring an electrical connection in order to detect the presence or movement of objects in the proximity of it.

20. Sensor structure according to claim 3, characterized in that the structure is suited to measuring an electrical connection in order to detect the presence or movement of objects in the proximity of it.
